(19) United States
(12) Patent Application Publication
(10) Pub. No.: US 2009/0155958 A1
(43) Pub. Date: Jun. 18, 2009

(54) ROBUST DIE BONDING PROCESS FOR LED DIES

(76) Inventors: Boris Kolodin, Beachwood, OH (US); Xiang Gao, Edison, NJ (US); Ivan Eliashevich, Maplewood, NJ (US); Stanton E. Weaver, JR., Northville, NY (US)

Correspondence Address: Fay Sharpe LLP, 1228 Euclid Avenue, 5th Floor, The Halle Building, Cleveland, OH, 44115, US

(21) Appl. No.: 11/955,787

(22) Filed: Dec. 13, 2007

(51) Int. Cl. H01L 21/60; B23K 1/06

(52) U.S. Cl. 438/120; 228/1.1; 257/E21.511

(57) ABSTRACT

Systems and methods are provided to mitigate excess die attachment material accrual, and parasitic conductive paths formed thereby. A die attachment material (e.g., solder) is melted using a combination of localized heat sources and ultrasonic energy. The heat sources bring the die attachment material close to its melting point, which reduces an amount of bonding force associated with purely ultrasonic bonding techniques. An ultrasonic transducer brings the die attachment material the rest of the way up to its melting point, which reduces the overall temperature that the die and/or sensitive components thereon endure during the bonding process.

### BACKGROUND

The subject innovation relates generally to die bonding systems and processes. It finds particular application in conjunction with light emitting diode (LED) dies, and will be described with particular reference thereto. However, it is to be appreciated that the systems and methods described herein are also amenable to other applications.

Conventional soldering die attachment processes (e.g., U.S. Pat. No. 6,222,207 B1; U.S. Pat. No. 6,593,160 B2) have limitations concerning flip chip bonding of LED vertical dies (e.g., such as Cree XB dies based on SiC substrates). Close proximity of the edge of the SiC substrate to metal on the bottom of the die can cause conductive path if residual die attachment material (such a solder) extends up the edge of the die and contacts the SiC (FIG. 1). Similar problems are experienced when a predefined pattern of conductive die attachment material (e.g., silver (Ag) filled epoxy) is used for flip chip bonding. When force is applied to reduce the thickness of an epoxy layer, die attachment material residue seeps out from beneath the dies, causing parasitic Ag—SiC Shottky diode-like behavior or a short circuit. Utilizing a B-stage curable Ag-filled epoxy (US Patent Application 20030042507) can reduce shunting probability, but Ag-filled epoxy has low thermal conductivity (e.g., 1.7-3.7 W/m*K) which is undesirable for power package applications. Widely used die attach methods based on solder bumps do not require mechanical pressure, but have relatively low solder bump thermal conductivity (˜30 W/m*K), complicated metallurgy, solder flux, and require under filing, all of which restrict method usage in high-current power package applications.

Ultrasonic flip chip bonding does not use die attachment material, bonding is accomplished in short period of time, the reliability of the connections is high due to metal bonding (e.g., Au—Au solid phase diffusion), and the technique is lead free. Typically, successful flip chip Au—Au interconnect techniques use Au terminated bumps (Au plated or Au stud bumps fabricated on the LED die or sub mount side).

However, conventional ultrasonic bonding requires applying significant force to the LED shaped substrate, and these shear forces within the substrate often exceed a failure threshold for the substrate, resulting in cracks and die damage. A similar “force issue” takes place in the ultrasonic bonded sapphire-based AlInGaN dies, which typically use thinner (e.g., a total die thickness of approximately 3-4 mm) sapphire substrates. Thinning or eliminating the sapphire substrate can result in die performance improvement but it further exacerbates mechanical strength issues for ultrasonic bonding. Ultrasonic bonding can be facilitated using pre-heated sub mount wafers, but that requires a long-time exposure of the wafer to high temperatures, causing a degradation of the wafer and soldering material.

Thus, there exists a need for systems and/or methods that overcome the above-mentioned deficiencies and others.

### BRIEF DESCRIPTION

According to one aspect, a die bonding system comprises a thermally conductive pickup tool that picks up a die, a heater that heats the pickup tool to a predetermined temperature, wherein the heated pickup tool heats a die attachment material that is employed to couple the die to a submount to a first temperature that is below the melting point of the die attachment material, and an ultrasonic transducer coupled to the pickup tool, wherein ultrasonic transducer heats the die attachment material to a second temperature that is equal to or greater than the melting point of the die attachment material.

According to another aspect, a method of bonding a die to a submount comprises positioning a die over a submount using a vacuum tool, conductively or remotely applying heat to the vacuum tool and conductively heating a die attachment material on the die to a first predetermined temperature, applying ultrasonic energy to the die to further heat the die attachment material to a second predetermined temperature, and applying a bonding force to the die to bond the die to the submount.

Yet another aspect relates to an apparatus for bonding a die to a submount, comprising means for positioning a die over a submount using a vacuum tool, means for applying heat to the vacuum tool and conductively heating a die attachment material on the die to a first predetermined temperature, means for applying ultrasonic energy to the die to further heat the die attachment material to a second predetermined temperature, and means for applying a bonding force to the die to bond the die to the submount.

### BRIEF DESCRIPTION OF THE DRAWINGS

FIG. 1 illustrates a die structure formed of multiple layers, including an LED layer that overlays a silicon carbide (SiC) layer.

FIG. 2 illustrates a system for performing a die attachment process, which may be employed to perform a die attachment process for bonding vertical and/or lateral LED chips in accordance with various aspects described herein.

FIG. 3A is an illustration of the system in a placement phase, wherein the die pickup tool with ultrasonic transducer has picked up the die and placed it in position for bonding.

FIG. 3B illustrates the system during a bonding stage, wherein heat is applied to the pickup tool to locally heat the die while an ultrasonic technique and a bonding force are applied to the die.

FIG. 3C illustrates timing diagram for bonding force, ultrasonic power and local die solder layer temperature during a bonding cycle.

FIG. 4 illustrates a method for bonding the die to the submount, in accordance with various aspects presented herein.

### DETAILED DESCRIPTION

Systems and methods are described herein, which facilitate reducing or eliminating excess die attachment material accrual and parasitic conductive paths formed in conjunction therewith by locally melting a die attachment material (e.g., solder) using a combination of localized heat sources and ultrasonic energy. The heat sources bring the die attachment material close to its melting point, which reduces an amount of bonding force required of purely ultrasonic bonding techniques. An ultrasonic transducer brings the die attachment material the rest of the way up to its melting point, which reduces the overall temperature that the die and/or sensitive components thereon endure during the bonding process.

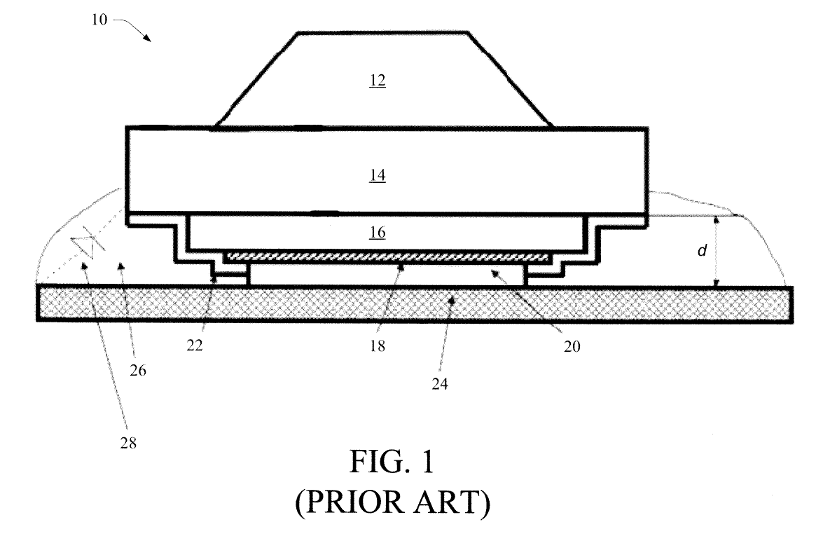

With reference to FIG. 1, a known die structure 10 is formed of multiple layers, including an LED layer 12 that overlays a silicon carbide (SiC) layer 14. The LED layer can comprise one LED or a plurality thereof. The SiC layer 14 overlays an epitaxial layer 16, which in turn is positioned over a silver (Ag) reflector layer 18. The Ag layer 18 is deposited over a die attachment layer 20, which can be a metal such as gold (Au) or a gold-tin alloy (e.g., Au—Sn) or the like. If die has just gold (Au) layer, the soldering die attachment process can employ a gold-tin alloy or other solder composition on the submount side. A passivation layer 22 coats exposed lower portions of the SiC, epitaxial, and Ag reflector layers, as well as the sides of the epitaxial and Ag reflector layers. The passivation layer 22 is also attached to an upper portion of the sides of the die attachment layer 20, and can be formed of, for example, a gold-tin alloy or the like.

The die attachment layer 20, such as soldering material, couples the die 10 to a submount 24. Additionally, excess die attachment material 26 is shown, which has been squeezed out from beneath the die structure during a conventional bonding process. The excess die attachment material provides a parasitic conductive path 28, which can exhibit Schottky diode-like conductivity. Additionally, a distance d illustrates a predetermined distance between the bottom of the SiC layer 14 and the top of the submount 24. In one example, the predetermined distance is approximately 5 micrometers. As mentioned above, a gold-gold interconnect (GGI) can be employed if gold stud bumps or gold terminated bumps are fabricated on the die or submount side.

The following figures describe systems and methods for mitigating the formation of the parasitic conductive path 28 and accumulation of the excess die attachment material 26, which can be undesirably formed using conventional bonding techniques.

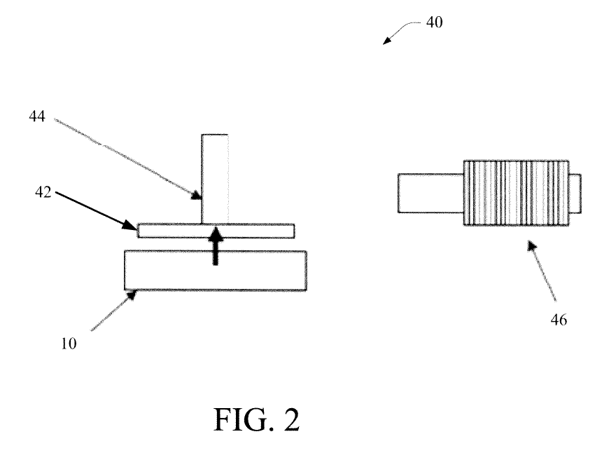

With reference to FIG. 2, a system 40 for performing a die attachment process is illustrated, which may be employed to perform a die attachment process for bonding vertical and/or lateral LED chips in accordance with various aspects described herein. The system includes a pickup tool 42 (e.g., a vacuum pickup tool or the like) on an ultrasonic transducer 44, which picks up the die structure 10. A heater 46 applies heat to the pickup tool 42 tool, and the applied heat is transferred to the die 10 during a die bonding process. The heater can supply enough heat to bring a solder or other die attachment material (not shown) close to its melting point, at which time the ultrasonic transducer can be activated to bring the solder temperature up to its melting point while a downward bonding force is applied to the die. The system thus concurrently applies thermal and ultrasonic energy (e.g., from the ultrasonic transducer) to achieve a solder composition melting point at selected locations when some predetermined amount of pressure is applied to a chip to maintain alignment of the chip and a submount (or board) during a bonding cycle.

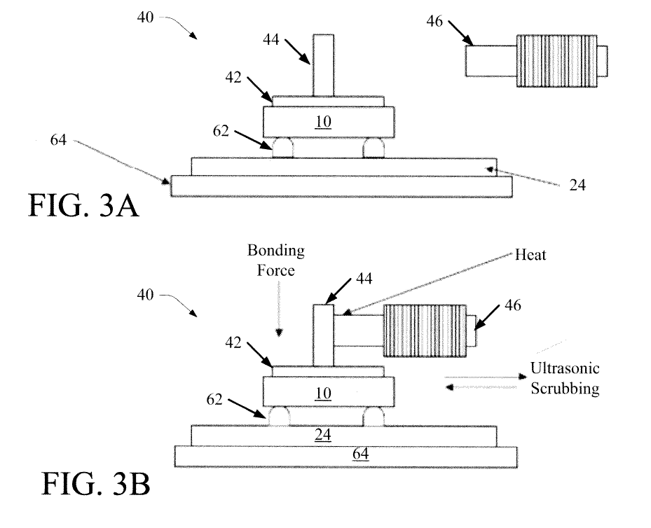

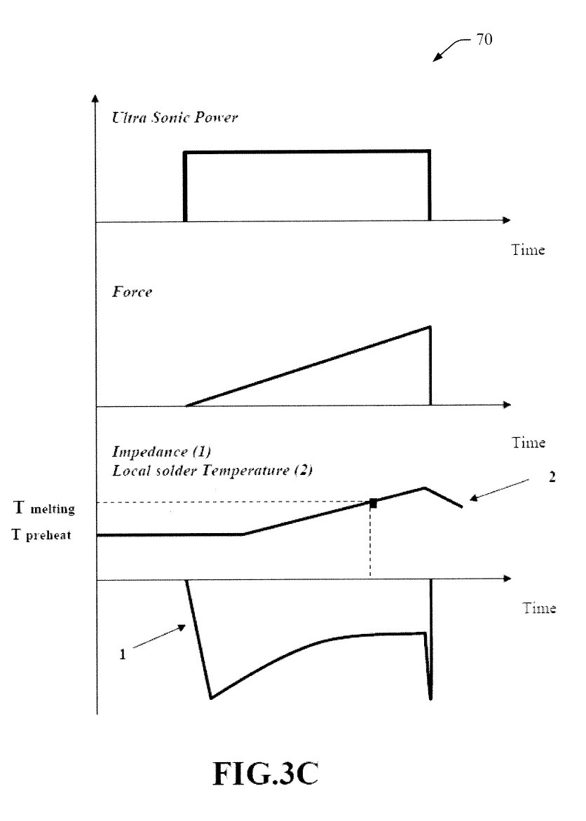

FIG. 3A is an illustration of the system 40 in a placement phase, wherein the die pickup tool 42 with ultrasonic transducer 44 has picked up the die 10 and placed it in position for bonding. A heater 46 is positioned near the pickup tool to apply heat to the tool when needed. A die bonding process is then performed, which provides localized die attach material melting to prevent die attach material residue from spreading, and thereby mitigate parasitic semiconductor structures or short circuit occurrences. For instance, a submount 24 is shown with thermally conductive nodes (bumps) 62 thereon, wherein the submount is positioned on a work holder 64. The holder 64 can be kept at a constant predetermined temperature. In one example, the holder 64 is maintained at approximately 150° C. However, it will be appreciated by those of skill that other temperatures may be employed depending on design parameters, user preferences, or the like.

FIG. 3B illustrates the system 40 during a bonding stage, wherein heat is applied to the pickup tool to locally heat the die while an ultrasonic scribing technique and a bonding force are applied to the die. The heater 46 is applied to the pickup tool 42, which holds the die in place over the thermally conductive nodes 62, while the ultrasonic transducer applies sound waves (e.g., at approximately 60 kHz or higher) as the tool 42 moves the die 10 back and forth over the submount 24 and thermally conductive nodes 62 to perform a scrubbing procedure. In one example, the heater 46 temporarily raises the temperature of the pickup tool 42 to approximately 300° C., while the holder 64 is maintained at a constant temperature of approximately 150° C. The heat, in combination with the vibration provided by the ultrasonic transducer and the bonding force applied equally over the die in a downward direction, facilitates bonding the die to the submount with minimal risk of damage to the chip and/or LED on the die.

The bonding process performed by the system 40 reduces and/or eliminates residual flux by locally melting die attachment material, or solder (not shown), which may be applied to the thermally conductive nodes and/or to the bottom of the substrate on the die at positions corresponding to the nodes. This in turn reduces the bonding pressure needed to bond the die to the submount, which reduces the risk of damage to the chip. For a wafer-level process, pre-bonded chips can be held at relatively low temperature because heat is applied to both the work holder and the pickup tool. Die attachment material is preliminary deposited onto the die and/or the conductive nodes, melted locally during a reflow stage, and thus localized within the interconnect area to prevent non-controlled spreading of die attachment material and/or to prevent unintended parasitic semiconductor structures or short circuits.

FIG. 3C illustrates time synchronization diagram 70 between force and ultra sonic energy during bonding cycle. As illustrated, bonding force is ramped up to a predetermined level during application of a substantially constant ultrasonic force. Heat is applied to maintain a first predetermined temperature (Tₚᵣₑₕₑₐₜ), and then increased to a second predetermined temperature (T_{melting}) approximately equal to the melting point of the solder material. Impedance is also illustrated as a function of time.

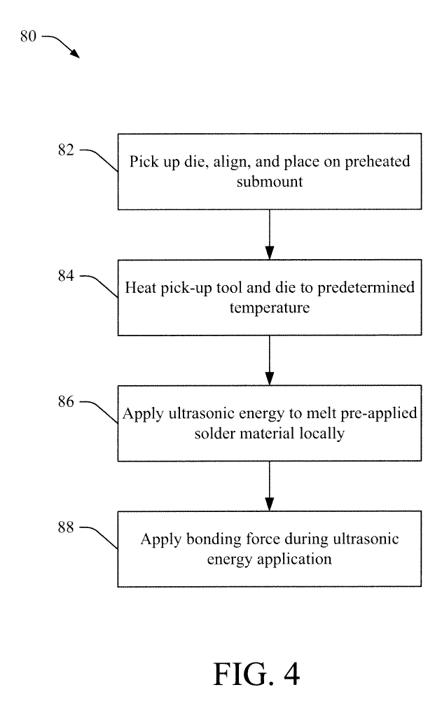

FIG. 4 illustrates a method 80 for bonding the die to the submount, in accordance with various aspects presented herein. At 82, the die is picked up (e.g., by a vacuum pickup tool or the like), aligned over a preheated submount surface, and placed on the submount. At 84, pickup tool is heated to bring the die to a predetermined temperature. At 86, ultrasonic energy is applied a to locally melt pre-applied solder material, which may be applied to the bottom surface of the die at predetermined locations, to the top surfaces of conductive nodes on the submount, or both. At 88, a bonding force is applied to the die, concurrently with the application of the ultrasonic energy, to bond the die to the submount.

A miniature heater can be applied to the pickup tool to heat the pickup tool, at 84, and can heat the tool, to a temperature lower that the melting point of the solder applied to the bonding surface(s). In one example, the solder is a gold-tin (Au—Sn) alloy with a melting point of approximately 280° C. When the solder is near its melting point, the ultrasonic energy is applied to melt the solder locally, where the thermally conductive nodes on the submount form a mechanical interconnect with contact pads on the die. In one example, the ultrasonic energy is applied for approximately 0.5-2.0 seconds. The solder can be deposited on contact pads on the bottom of the die or on the submount nodes, or both. The bonding force magnitude is a function of the number of nodes on the submount, and can be on the order of approximately 200-800 grams, thereby significantly reducing an amount of force needed for conventional ultrasonic bonding techniques. Additionally, submount wafer or printed circuit board (in the chip-on-board case) can be kept at acceptable temperatures for InAlGaN-based dies during processing of a whole wafer (board).

As mentioned above, the bonding method thus combines ultrasonic and thermal energy to provide local soldering conditions for bumped submount and die. That is, ultrasonic energy provides an extra local source of heat to reach the solder melting point in the locations where Au plated nodes have mechanical contact with appropriate Au—Sn contact pads on the die side. It will be appreciated that other solder compositions can be used, including but not limited to silver-tin-copper (Ag—Sn—Cu) lead free solders, tin (Sn), etc.

Various embodiments and examples of the innovation have been described herein. It is appreciated that modifications and alterations will occur to others upon reading and understanding the preceding detailed description. It is intended that the exemplary embodiments be construed as including all such modifications and alterations insofar as they come within the scope of the appended claims or the equivalents thereof.

1. A die bonding system, comprising:
a thermally conductive pickup tool that picks up a die;
a heater that heats the pickup tool to a predetermined temperature, wherein the heated pickup tool heats a die attachment material that is employed to couple the die to a submount to a first temperature that is below the melting point of the die attachment material; and
an ultrasonic transducer coupled to the pickup tool, wherein ultrasonic transducer heats the die attachment material to a second temperature that is equal to or greater than the melting point of the die attachment material.

2. The system of claim 1, wherein the die attachment material is formed of at least one of gold-tin (Au—Sn) alloy, silver-tin-copper (Ag—Sn—Cu), or tin (Sn).

3. The system of claim 1, wherein the die attachment material is formed of a gold-tin (Au—Sn) alloy.

4. The system of claim 3, wherein the pickup tool is heated to approximately 300° and heats the die attachment material conductively, and wherein the first temperature is approximately 240° C.

5. The system of claim 4, further comprising a heating holder on which the submount is positioned, wherein the heating holder is thermally isolated from a machine base and is maintained at a constant third temperature to assist in heating the die attachment material.

6. The system of claim 5, wherein the third temperature is below the melting point of the die attachment material.

7. The system of claim 6, wherein the third temperature is approximately 150° C.

8. The system of claim 4, wherein the ultrasonic transducer heats the die attachment material to the second temperature, which is in the range of approximately 280-310° C.

9. The system of claim 8, wherein the submount comprises thermally conductive bumps to which the die is bonded.

10. The system of claim 9, wherein a bonding force is applied to the die when the die attachment material is approaching the second temperature.

11. A method of bonding a die to a submount, comprising:
positioning a die over a submount using a vacuum tool;
conductively or remotely applying heat to the vacuum tool and conductively heating a die attachment material on the die to a first predetermined temperature;
applying ultrasonic energy to the die to further heat the die attachment material to a second predetermined temperature; and
applying a bonding force to the die to bond the die to the submount.

12. The method of claim 11, wherein the die attachment material is formed of a gold-tin (Au—Sn) alloy.

13. The method of claim 12, wherein the vacuum tool is heated to approximately 300° C. and heats the die attachment material conductively and wherein the first temperature is approximately 240° C.

14. The method of claim 13, further comprising preheating a holder on which the submount is positioned, and maintaining the holder at a constant third temperature.

15. The method of claim 14, wherein the constant third temperature is below the melting point of the die attachment material.

16. The method of claim 15, wherein the constant third temperature is approximately 150° C.

17. The method of claim 13, wherein the ultrasonic transducer heats the die attachment material to the second predetermined temperature, which is in the range of approximately 280-310 C.

18. The method of claim 17, further comprising applying a bonding force the die when the die attachment material has reached the second predetermined temperature, and bonding the die to thermally conductive bumps on the submount.

19. An apparatus for bonding a die to a submount, comprising:
means for positioning a die over a submount using a vacuum tool;
means for applying heat to the vacuum tool and conductively heating a die attachment material on the die to a first predetermined temperature;
means for applying ultrasonic energy to the die to further heat the die attachment material to a second predetermined temperature; and
means for applying a bonding force to the die to bond the die to the submount.

20. The apparatus of claim 19, further comprising means for preheating a holder on which the submount is positioned to a constant third temperature.
